(19) United States
(12) Patent Application Publication
(10) Pub. No.: US 2026/0251697 A1
(43) Pub. Date: Aug. 27, 2026

(54) Device with a Signal Amplifier Integrated Into a Semiconductor Chip

(71) Applicant: TDK-Micronas GmbH, Freiburg im Breisgau (DE)

(72) Inventors: Nils Remmers, Schopfheim (DE); David Muthers, Denzlingen (DE)

(21) Appl. No.: 19/535,515

(22) Filed: Feb. 10, 2026

(30) Foreign Application Priority Data
Feb. 11, 2025 (DE) 202025100675.8

(51) Int. Cl. G01R 31/28; H03F 1/12

(52) U.S. Cl. CPC G01R 31/2856; G01R 31/2837; H03F 1/12

(57) ABSTRACT

A device with a signal amplifier integrated into a semiconductor chip has an amplifier input for an input signal and an amplifier output for an output signal. The signal amplifier has at least two amplifier levels connected in series between the amplifier input and the amplifier output. A feedback network is arranged between the amplifier input and the amplifier output. A fault detection circuit is integrated into the semiconductor chip to detect a faulty modulation of the output signal caused by a fault in the circuitry of the integrated circuit. The fault detection circuit has a comparator that is designed to compare a comparator input signal present on a comparator input of the comparator with a predetermined tolerance value or a tolerance range. A comparator input is connected to a node of the signal amplifier, whereby on the node a signal can be output that is more strongly modulated than the input signal.

### CROSS-REFERENCE TO RELATED APPLICATION

This application claims priority to German Patent Application No. 202025100675.8 filed Feb. 11, 2025, the disclosure of which is hereby incorporated by reference in its entirety.

### BACKGROUND OF THE INVENTION

### Field of the Invention

The invention relates to a device with a signal amplifier integrated into a semiconductor chip, which amplifier has an amplifier input for an input signal and an amplifier output for an output signal, where the signal amplifier has at least two amplifier levels connected in series between the amplifier input and the amplifier output, and a feedback network arranged between the amplifier input and the amplifier output, with a fault detection circuit integrated into the semiconductor chip to detect a faulty modulation of the output signal caused by a fault in the circuitry of the integrated circuit, where the error detection circuit has a comparator that is designed to compare a comparator input signal present on a comparator input of the comparator with a predetermined tolerance value or a tolerance range.

### Description of Related Art

Sensor technology is constantly gaining in importance in the automotive engineering sector. In particular, when sensor technology is used in safety applications, there are very high requirements, not only in terms of precision, but also in terms of sensor signal reliability. In accordance with the state of the art, redundant design, including system plausibility checks, increases system reliability.

As an alternative to redundancy, relevant signal paths in the systems are monitored or, in terms of known sources of interference or effects, are designed to be fault resilient through compensating architectures.

Particularly in the area of electronic circuit architecture in conjunction with physical sensors, many approaches that lead to highly robust systems are known. A generic example of this is the temperature compensation of circuit and sensor that is intrinsic in modern sensor systems. And other effects, such as those associated with electromagnetic compatibility (EMC), are already compensated for with satisfactory results, in part.

The prerequisite for good and reliable compensation is precise knowledge of the mechanisms of action with which the disturbances are entered into the sensor system.

Among the less well specified mechanisms of action are, in particular, faults resulting from the failure or malfunction of components involved in the function of the overall system. In this case, disturbance compensation fails and reliability is ensured only through diagnostic instances that permanently monitor operation of the systems. A faulty output signal can no longer be prevented in this case, but it can at a minimum be detected and signaled to a higher system instance.

In the case of monolithic integrated sensor systems or integrated circuits (ICs) in general, external circuitry is also among the system components potentially causing faults, including the input periphery of an evaluation unit to which the data or sensor signals are transmitted.

In many application scenarios, the output signals are present as differential or absolute output voltages. An output amplifier drives the external load, which is comprised of ohmic, capacitive, and inductive components and is also partially of a parasitic type.

If the failures mentioned produce a change in load, voltage deviations from an overload of the output amplifier can result.

While large deviations from the internally prescribed nominal value, for example caused by short circuits, can be very easily detected because of the size of the deviation, smaller deviations of only a few mV, produced by a moderately elevated load current can only be detected with significantly greater effort.

In practice, a device of the type mentioned above is known, having a first signal amplifier that has several amplifier levels and is integrated into a semiconductor chip. The first signal amplifier has an amplifier input for a variable input signal and an amplifier output for an output signal. An error detection circuit is integrated Into the semiconductor chip, which circuit has a second signal amplifier identical to the first signal amplifier, whose amplifier input is connected to the amplifier input of the first signal amplifier. The error detection circuit in addition has a differential amplifier, which is connected with its non-inverting input to the amplifier output of the first signal amplifier and which is connected, with its inverting input, to the amplifier output of the second signal amplifier. To detect deviations of output signals of the signal amplifiers outside a prescribed tolerance range, the output of the differential amplifier is connected to the input of a comparator. If smaller deviations are to be detected, the error detection circuit must have a correspondingly high level of precision. It is also unfavorable that the second signal amplifier requires a not insignificant circuit complexity.

### SUMMARY OF THE INVENTION

The task of the invention therefore is to specify a device of the type mentioned above whose fault detection circuit enables a simple and cost-effective design, but which nevertheless can detect faulty circuitry of the integrated circuit that only causes small deviations from a nominal output signal in the output signal.

This task is accomplished with the characteristics described herein. With a device of the type mentioned above, this stipulates that a comparator input of the comparator is connected to a node of the signal amplifier arranged between two amplifier levels, and that the signal amplifier is designed such that a signal that is more strongly modulated than the input signal can be output on the node.

One advantage of the device according to the invention is that the first amplifier level of the multiple level amplifier typically can have a high amplification factor of greater than 1000, while the last amplifier level, also called the output level, has driver capability rather than a high signal amplification or a high amplification factor. Thus, for deviations of the output signal in the millivolt range, for example, deviation signals in the volt range can appear in the node between the amplifier levels. As such, deviations in the output signal caused by faulty circuitry of the semiconductor chip can be detected in an easy manner, using a simple comparator whose thresholds are aligned with the normal amplitude of the signal present on the node. As a consequence, the threshold value specifications of the comparator, through which the tolerance value or a tolerance range of the comparator is defined, which leads to detection of the fault, can also be designed with generous precision in the range of several 10 mV, which can be accomplished in circuitry with little effort. The fault of the circuitry of the integrated circuit can, in particular, include the connection of an overly low load impedance at the amplifier output.

In a preferred embodiment of the invention, the comparator is designed as a window comparator. The detection circuit thus enables a two-sided check of the signal present at the comparator input. The detector circuit can hereby more reliably detect faults for specific applications.

A further development of the invention provides that the comparator includes at least one comparator element that has an inverting and a non-inverting comparator element input, that one of these comparator element inputs is connected to the comparator input and the other comparator element input is connected to a limit value transmitter, by means of which a limit signal can be created on the latter comparator element input, and that the limit value transmitter has a mechanism for the dynamic adaptation of the limit signal to the temperature and/or the amplitude of the input signal. The detection circuit thus enables even more reliable error detection.

In an advantageous embodiment of the invention, the fault detection circuit has a low-pass filter. The fault detection circuit thus enables a more reliable function when EMC interference occurs or for fast load changes.

In the simplest case, the amplifier is designed in two levels, and the node to which the comparator input of the window comparator is connected is arranged between the first and second amplifier level. In this configuration the output of the first amplifier level is connected to the input of the second amplifier level and the input of the detection circuit.

In a preferred embodiment of the invention, the low-pass filter has a low-pass input connected to the node and a low-pass output connected to the comparator input. Thus the output of the comparator can form the output of the detection circuit. The use of a low-pass filter before the comparator limits the input bandwidth and thereby attenuates the sensitivity of the detection circuit. Fast load changes, in particular capacitative, lead temporarily to strong modulation of the nodes between the amplifier levels. The detection circuit would respond to this, if necessary. The low-pass filter in this case prevents the detection circuit from triggering.

In a further development of the invention, the low-pass filter is designed as an RC filter of the first order.

It is advantageous if the comparator designed as a window comparator has two comparator elements and a digital gate of type NAND or AND, where the output of the digital gate forms the output of the window comparator. The two comparator elements serve to establish the upper and lower limit for the response of the detection circuit. Using the respective reference inputs of the comparator elements, the upper threshold value and lower threshold value for the window comparator are specified. If the signal that is filtered by the low-pass and present on the node exceeds the upper threshold value, the corresponding comparator output switches from logical ONE to ZERO. If the signal, which is filtered by the low-pass, and present on the node, falls below the lower threshold value, the corresponding comparator output switches from logical ONE to ZERO. The inputs of the digital gate are linked to the outputs of the two comparator elements. Depending on the definition, exceeding or falling below the corresponding threshold value, which corresponds to a fault, can then be coded in a ONE or ZERO digital output state. A NAND or an AND gate is particularly suited to this.

In an advantageous embodiment of the invention, the signal amplifier has more than two amplifier levels. In this case, the node connected to the comparator input is arranged between the second to last and last amplifier level.

### BRIEF DESCRIPTION OF THE DRAWINGS

Additional details, characteristics, and benefits of the present invention can be determined from the following description of exemplary embodiments, taking into account the drawing.

The terms Fig., Figs., Figure, and Figures are used interchangeably in the specification to refer to the corresponding figures in the drawings.

The figures show:

FIG. 1 a device with a four-level signal amplifier, which is designed as a voltage signal amplifier, and with a fault detection circuit, which is integrated into a semiconductor chip,

FIG. 2 a schematic of a fault detection circuit, and

FIG. 3 an exemplary embodiment of a device with a two-level signal amplifier, which is designed as a voltage signal amplifier.

### DESCRIPTION OF THE INVENTION

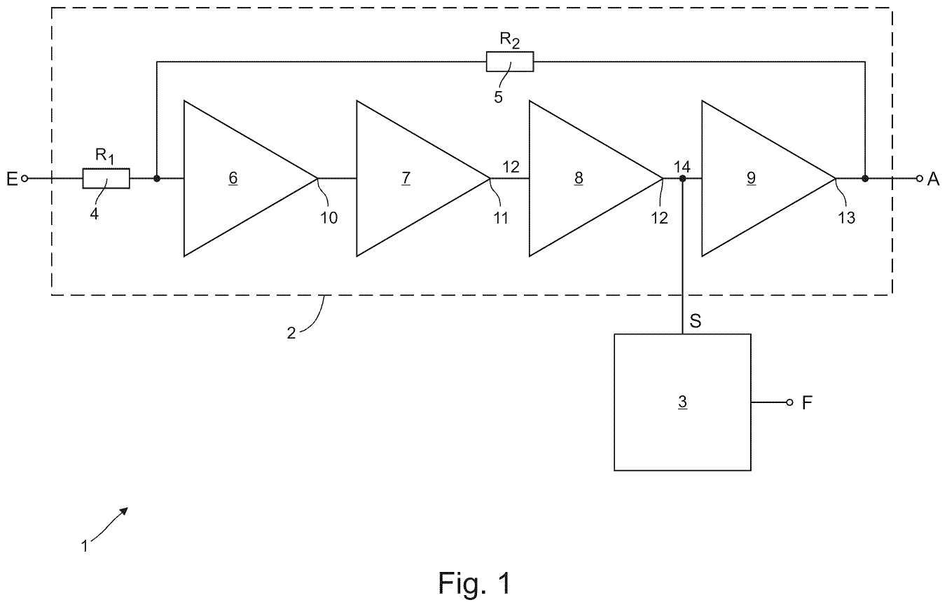

FIG. 1 shows a block schematic of a first exemplary embodiment of a device identified as a whole as 1, which has a signal amplifier 2, integrated into a semiconductor chip, with an amplifier input E to apply a variable input signal, an amplifier output A to output an output signal, and a fault detection circuit 3 to detect a faulty modulation of the output signal caused by a fault in the circuitry of the integrated circuit. Between the amplifier input E and amplifier output A, the signal amplifier 2 has a feedback network, which has a first feedback impedance 4 and a second feedback impedance 5 connected to it in series.

The signal amplifier 2 has four amplifier levels 6, 7, 8, 9 connected in series, each of which has an input and an output 10, 11, 12, 13. The amplifier input E is connected by means of the first feedback impedance 4 to the input of the first amplifier level 6. The output 10 of the first amplifier level 6 is connected to the input of a second amplifier level 7. The output 11 of the second amplifier level 7 is connected to the input of a third amplifier level 8, whose output 12 is connected to the input of a fourth amplifier level 9 by means of a node 14. The output 13 of the fourth amplifier level 9 is connected to the amplifier output A of the signal amplifier 2 and connected to the input of the first amplifier level 6 by way of the second feedback impedance 5. The node 14 is connected to a signal tap S of the fault detection circuit 3.

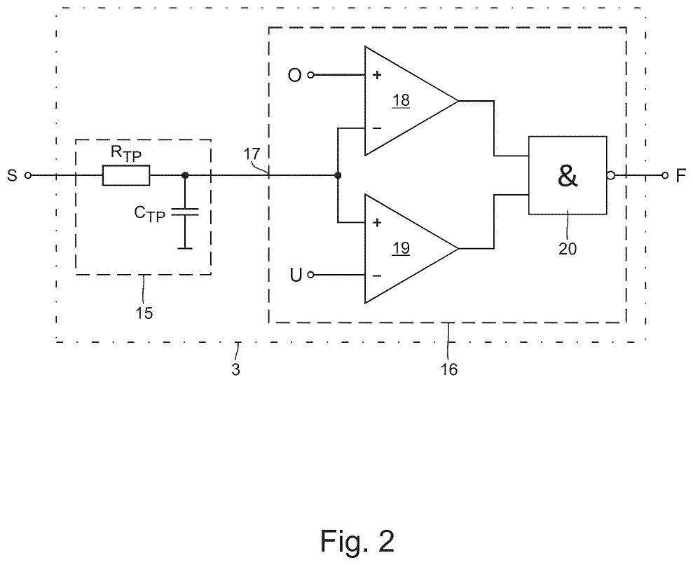

As can be seen in FIG. 2, the fault detection circuit 3 has a low-pass filter 15 and a comparator 16, which is designed as a window comparator. The low-pass filter 15 comprises a resistor RTP and a capacitor CTP. A comparator input 17 of the comparator 16 is connected for threshold monitoring, by means of the resistor RTP, to the signal tap S of the fault detection circuit 3, and by means of the capacitor CTP, to a connector for a reference potential. The comparator 16 contains two comparator elements 18 and 19 designed as operational amplifiers and a NAND gate 20. A first comparator element 18 has a first, inverting comparator element input, which is connected to the comparator input 17 of the window comparator 16 and to a non-inverting comparator element input of a second comparator element 19. A non-inverting comparator element input O of the first comparator element 18 is connected to a transmitter, not shown in detail in the drawing, for an upper threshold value, and an inverting comparator element input U of the second operational amplifier 19 is connected to a transmitter not shown in detail in the drawing, for a lower threshold value. The upper threshold value and lower threshold value define a tolerance range within which the voltage on the comparator input 17 may lie during fault-free operation of the signal amplifier 2.

If the potential on the comparator input 17 is higher than the upper threshold value, a first voltage corresponding to the logical ZERO value is present at the output of the first comparator element 18. If the potential on the comparator input 17 is lower than the upper threshold value, a second voltage corresponding to the logical ONE value is present at the output of the first comparator element 18.

In a corresponding manner, the second voltage (logical ONE) is present on the output of the second comparator element (19) when the potential on the comparator input 17 is higher than the lower threshold value. If the potential on the comparator input 17 is lower than the lower threshold value, a first voltage corresponding to the logical ZERO value is present at the output of the second comparator element 19.

The output of the first comparator element 18 is connected to a first input of the NAND gate 20, and the output of the second operational amplifier 19 is connected to a second input of the NAND gate 20. The output F of the NAND gate 20 forms the output of the fault detection circuit 3. During operation of the device 1, a signal is output at the output F, which signal indicates whether the potential on the comparator input 17 is within the tolerance range defined by the lower threshold value and the upper threshold value.

If the potential present on the comparator input 17 exceeds the potential on the comparator element input O, or falls below the potential on the comparator element input U, the signal on output F switches from logical ZERO to logical ONE. If the potential present on the comparator input 17 is within the tolerance range delineated by the potentials present on comparator element inputs O and U, output F is at logical ZERO.

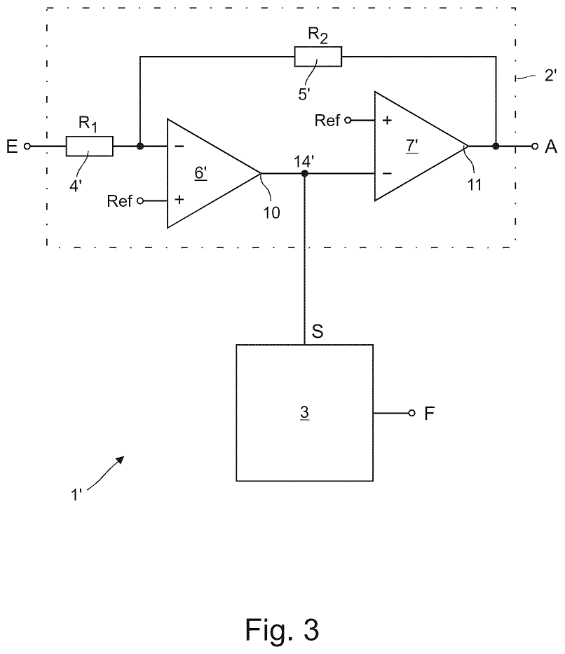

FIG. 3 shows a second exemplary embodiment of a device 1′ according to the invention, which has a two level signal amplifier 2′ with an amplifier input E and an amplifier output A. In this exemplary embodiment, the amplifier input E is connected, by way of a first feedback impedance 4′, to an inverting input of a first amplifier level 6′ and is connected by way of a second feedback impedance 5′, to the output A of the signal amplifier 2′. A non-inverting input of the first amplifier level 6′ is at a reference potential Ref.

The output 10 of the first amplifier level 6 is connected to a node 14′ and to an inverting input of a second amplifier level 7′. An inverting input of the second amplifier level 6′ is at the reference potential Ref.

The output 11 of the second amplifier level 7 is connected to the amplifier output A of the signal amplifier 1, and connected to the inverting input of the first amplifier level 6′ by way of the second feedback impedance 5′. The feedback network formed by the feedback impedances 4′, 5′ generates the feedback factor R1/(R1+R2) and configures the arrangement as an inverting amplifier.

The node 14′ is connected to a signal tap S of the fault detection circuit 3 shown in FIG. 2. This corresponds to the fault detection circuit 3 of the first exemplary embodiment shown in FIG. 1. The description of the first exemplary embodiment applies accordingly to the second exemplary embodiment.

It should still be noted that the device according to the invention can also be built in bipolar or BiCMOS circuit technology. Possibly then, the comparators can be designed not as voltage comparators but rather as current comparators.

1. A device with a signal amplifier integrated into a semiconductor chip, which amplifier has an amplifier input for an input signal and an amplifier output for an output signal, whereby the signal amplifier, has at least two amplifier levels connected in series between the amplifier input and the amplifier output, and a feedback network arranged between the amplifier input and the amplifier output, and with a fault detection circuit integrated in the semiconductor chip to detect a faulty modulation of the output signal caused by a fault in the circuitry of the integrated circuit, whereby the fault detection circuit has a comparator which is designed to compare a comparator input signal present on the comparator input of the comparator with a predetermined tolerance value or a tolerance range, wherein a comparator input of the comparator is connected to a node of the signal amplifier arranged between two amplifier levels, and that the signal amplifier is designed such that on the node, a signal can be output that is more strongly modulated than the input signal.

2. The device according to claim 1, wherein the comparator is designed as a window comparator.

3. The device according to claim 1, wherein the comparator comprises at least one comparator element, which has an inverting and a non-inverting comparator element input, that one of these comparator element inputs is connected to the comparator input and the other comparator element input is connected to a limit value transmitter, by means of which a limit value signal can be applied on the latter comparator element input, and that the limit value transmitter has a mechanism for the dynamic adaptation of the limit value signal to the temperature and/or the amplitude of the input signal.

4. The device according to claim 1, wherein the fault detection circuit has a low-pass filter.

5. The device according to claim 4, wherein the low-pass filter has a low-pass input connected to the node and a low-pass output connected to the comparator input and that the output of the comparator preferably forms the output of the detection circuit.

6. The device according to claim 4, wherein the low-pass filter is designed as an RC filter of the first order.

7. The device according to claim 2, comparator designed as a window comparator has two comparator elements and a digital gate, preferably of type AND or NAND, and that the output of the digital gate forms the output of the window comparator.

8. The device according to claim 7, wherein the signal amplifier has more than two amplifier levels, and that the node connected to the comparator input is arranged between the second to last and last amplifier level.
